(19) United States
(12) Patent Application Publication
(10) Pub. No.: US 2011/0156485 A1
(43) Pub. Date: Jun. 30, 2011

(54) SEMICONDUCTOR INTEGRATED CIRCUIT DEVICE

(75) Inventor: Shohei Kosai, Yokohama-shi (JP)

(73) Assignee: KABUSHIKI KAISHA TOSHIBA, Tokyo (JP)

(21) Appl. No.: 12/724,190

(22) Filed: Mar. 15, 2010

(30) Foreign Application Priority Data
Dec. 25, 2009 (JP) 2009-296268

(51) Int. Cl. H02J 4/00; H03H 5/00; H02J 1/00; H02J 1/10

(52) U.S. Cl. 307/80; 323/369; 307/77; 307/43

(57) ABSTRACT

A semiconductor integrated circuit device includes a driving-voltage generating circuit including a diode-connected rectifying element and a resistor element as a voltage generating source, one end of which is connected to one end of the rectifying element and the other end of which is connected to a ground potential, wherein a voltage generated by the resistor element is output to the other end of the rectifying element as a driving voltage.

### CROSS-REFERENCE TO RELATED APPLICATIONS

This application is based upon and claims the benefit of priority from the prior Japanese Patent Application No. 2009-296268, filed on Dec. 25, 2009; the entire contents of which are incorporated herein by reference.

### BACKGROUND OF THE INVENTION

1. Field of the Invention

The present invention relates to a semiconductor integrated circuit device.

2. Description of the Related Art

According to the rapid development of semiconductor devices and radio technologies in recent years, the radio technologies are used in various situations. Radio communication not requiring a cable for communication is applied in various ways. However, a driving voltage necessary for the operation of an internal circuit and the like of a communication apparatus needs to be supplied from a battery, an AC power supply, or the like set on the outside of the apparatus. As means for solving such a problem, for example, related arts represented by Japanese Patent No. 3398880 and Japanese Patent Application Laid-Open No. 2006-197734 propose a method of transmitting electric power by radio as well.

However, in the method in the past, a device that transmits electric power to the communication apparatus is necessary. Unless the device is not provided, naturally, the internal circuit and the like cannot be actuated. Therefore, it is difficult to perform voluntary transmission of information.

It is an object of the present invention to provide a semiconductor integrated circuit device that obtains a driving voltage from atmospheric temperature using a semiconductor process.

### BRIEF SUMMARY OF THE INVENTION

A semiconductor integrated circuit device according to an embodiment of the present invention comprising a driving-voltage generating circuit including a diode-connected rectifying element and a resistor element as a voltage generating source, one end of which is connected to one end of the rectifying element and the other end of which is connected to a ground potential, wherein a voltage generated by the resistor element is output to the other end of the rectifying element as a driving voltage.

A semiconductor integrated circuit device, wherein one end of a diode-connected first rectifying element and one end of a first resistor element as a voltage generating source are connected to form a first driving-voltage generating circuit and a plurality of the first driving-voltage generating circuits are connected to form a first driving-voltage generating unit, one end of a diode-connected second rectifying element and one end of a second resistor element as a voltage generating source are connected to form a second driving-voltage generating circuit and a plurality of the second driving-voltage generating circuits are connected to form a second driving-voltage generating unit, and the first and second driving-voltage generating units are connected in series or parallel.

### BRIEF DESCRIPTION OF THE DRAWINGS

FIG. 1 is a diagram of the configuration of a semiconductor integrated circuit device according to a first embodiment of the present invention;

FIG. 2 is a diagram of an equivalent circuit of the semiconductor integrated circuit device shown in FIG. 1;

FIG. 3 is a diagram of the configuration of a semiconductor integrated circuit including a transistor instead of a resistor shown in FIG. 1;

FIG. 4 is a diagram of a simulation circuit modeled after the semiconductor integrated circuit device shown in FIG. 3;

FIG. 5 is a graph of a change in an output voltage obtained by the simulation circuit shown in FIG. 4;

FIG. 6 is a diagram of a configuration example in which a plurality of the semiconductor integrated circuit devices shown in FIG. 3 are connected in series;

FIG. 7 is a diagram of a configuration example in which a plurality of the semiconductor integrated circuit devices shown in FIG. 3 are connected in parallel;

FIG. 8 is a diagram of a configuration example in which a plurality of sets of the semiconductor integrated circuit devices connected in parallel shown in FIG. 7 are further connected in series;

FIG. 9 is a diagram of a configuration example in which a plurality of sets of the semiconductor integrated circuit devices connected in series shown in FIG. 6 are further connected in parallel;

FIG. 10 is a diagram of the configuration of a semiconductor integrated circuit device according to a second embodiment of the present invention;

FIG. 11A is a diagram of a configuration example in which semiconductor integrated circuit devices including PMOSs and semiconductor integrated circuit devices including NMOSs are connected in series;

FIG. 11B is a diagram of a configuration example in which semiconductor integrated circuit devices including PMOSs and semiconductor integrated circuit devices including NMOSs are connected in parallel;

FIG. 12 is a diagram of a configuration example in which a plurality of sets of the semiconductor integrated circuit devices connected in series shown in FIG. 11A are further connected in parallel;

FIG. 13 is a diagram of a configuration example in which a plurality of sets of the semiconductor integrated circuit devices connected in parallel shown in FIG. 11B are further connected in series;

FIG. 14 is a diagram of the configuration of a transistor according to a fifth embodiment of the present invention;

FIG. 15 is a graph of a change in an output voltage that occurs when a general n-type transistor is used and a change in an output voltage that occurs when an n-type transistor shown in FIG. 14 is used;

FIG. 16 is a diagram for explaining an example in which a load is driven by a control unit and a power generating unit;

FIG. 17 is a diagram of an example in which the power generating unit and the control unit are integrated on one LSI;

FIG. 18 is a diagram of one example in which the power generating unit and the control unit are integrated on a SoC;

FIG. 19 is a diagram of the other example in which the power generating unit and the control unit are integrated on the SoC; and

FIG. 20 is a diagram for explaining an example in which a load is driven by using a larger number of power generating units.

### DETAILED DESCRIPTION OF THE INVENTION

Exemplary embodiments of a semiconductor integrated circuit device according to the present invention will be explained below in detail with reference to the accompanying drawings. The present invention is not limited to the following embodiments.

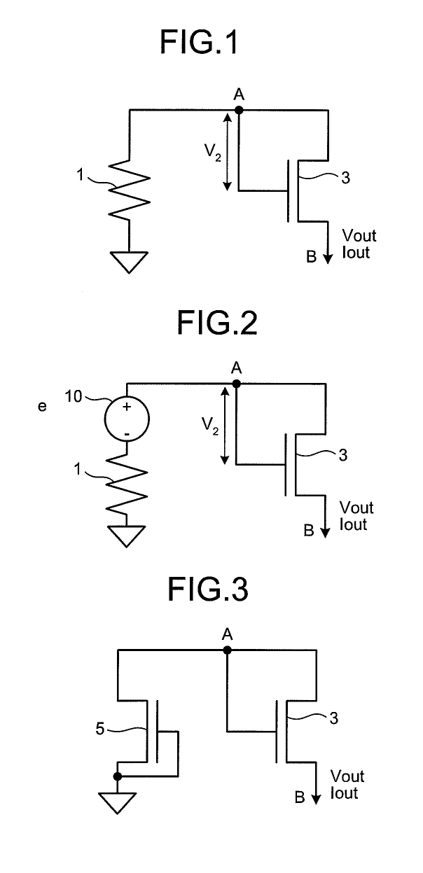

FIG. 1 is a diagram of the configuration of a semiconductor integrated circuit device according to a first embodiment of the present invention. FIG. 2 is a diagram of an equivalent circuit of the semiconductor integrated circuit device shown in FIG. 1. The semiconductor integrated circuit device shown in FIGS. 1 and 2 includes a diode-connected transistor (a rectifying element) 3 and a resistor (a resistor element) 1 as a voltage generating source, one end of which is connected to one end of the transistor 3 and the other end of which is connected to a ground potential (hereinafter, “GND”).

A principle of output of a DC voltage Vout and a DC current Iout is explained below. First, in a resistor 1 having a resistance R, voltage by thermal noise is generated. Magnitude e of a RMS value of a noise voltage source 10 as a source of the voltage can be represented by Formula (1) per a unit frequency when absolute temperature of the atmosphere is represented as T an the Boltzmann constant is represented as k:

e²=4 kTR (1)

Voltage v2 generated at a connection end of a gate and a drain of the transistor 3 (hereafter simply referred to as “node A”) can be represented by the following Formula (2) as a function of a frequency f:

$${v}_{2} = \frac{e}{1 + 2 π fCR} \qquad ( 2 )$$

where, C represents capacitance attached to the node A.

The capacitance C includes gate capacitance, gate-to-source capacitance, and drain-to-back gate capacitance. A part of the voltage v2 applied to the node A is converted into a DC current and appears at a source (a node B) of the transistor 3. A noise voltage v up to a band ½πCR can be represented by the following Formula (3);

$$\begin{matrix}v = e ( 0 < f < \frac{1}{2 π CR} ) \\ = 0 ( \frac{1}{2 π CR} < f )\end{matrix} \qquad ( 3 )$$

The DC current Iout can be represented by the following Formula (4) when a nonlinear effect of the transistor 3 is approximated by a square. In a relation indicated by Formula (4), the DC current Iout is proportional to a product of a gate voltage Vg and a drain voltage Vd. This is because the transistor 3 is diode-connected. In a general transistor, the DC current Iout is proportional to the square of the gate voltage Vg or the square of the drain voltage Vd.

$$Iout ∝ Vg * Vd = {\int }_{0}^{\frac{1}{2 π RC}} {e}^{2} d f = \frac{4 kT}{2 π C} \qquad ( 4 )$$

According to Formula (4), to extract as large a DC current Iout as possible, it is necessary to reduce the capacitance C. This is because it is important to convert the noise voltage v from the noise voltage source (the noise voltage source 10) into a DC voltage in as wide a band as possible.

To obtain a larger nonlinear effect, it is desirable to set a threshold voltage Vth of the transistor 3 to a value smaller than 0 volt. For example, an electric current that flows when a predetermined gate voltage Vg is applied in the transistor 3, the threshold voltage Vth of which is set low, indicates a large value compared with an electric current that flows when the gate voltage Vg equivalent to that explained above is applied in the transistor 3, the threshold voltage Vth of which is set high.

When an n-type substrate is used, the threshold voltage Vth of the transistor 3 and capacitance between a drain and a back gate can be reduced.

However, in an actual circuit, problems explained below are present. (1) To increase the voltage v2 generated at the node A, it is necessary to increase the resistance R of the resistor 1 to a large value, for example, equal to or larger than several kilo-ohms. (2) Even if the resistance R is increased, because the voltage v₂ generated at the node A is small, for example, about 1 millivolt and because of parasitic capacitance of the resistor 1, it is difficult to extract an actual device voltage.

FIG. 3 is a diagram of the configuration of a semiconductor integrated circuit device including a transistor 5 instead of the resistor 1 shown in FIG. 1. The semiconductor integrated circuit device shown in FIG. 3 is a semiconductor integrated circuit device for solving the problem. One end of the diode-connected transistor 5 is connected to one end of the transistor 3 and the other end thereof is connected to the GND.

Because a resistor realized by the transistor 5 has a small area, it is possible to reduce the parasitic capacitance compared with that in the semiconductor integrated circuit device including the resistor 1. Therefore, it is easy to obtain the DC current Iout from the viewpoint of Formula (4).

The transistor 5 has a small area and is used as a resistance component indicating a high resistance. If the resistance of the transistor 5 is set smaller than the input impedance of the transistor 3 acting as a diode, it is possible to obtain a large quantity of electric current. Specifically, it is desirable that the threshold voltage Vth of the transistor 5 is lower than the threshold voltage Vth of the transistor 3 by, for example, about 50 millivolts.

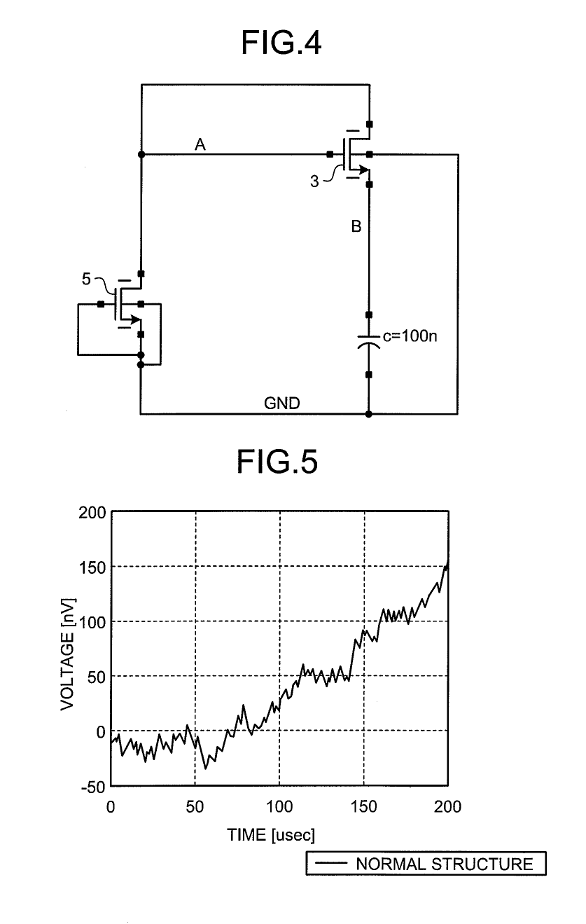

FIG. 4 is a diagram of a simulation circuit modeled after the semiconductor integrated circuit device shown in FIG. 3. FIG. 5 is a diagram of a change in an output voltage obtained by the simulation circuit shown in FIG. 4. The transistors 5 and 3 shown in FIG. 4 correspond to the respective transistors shown in FIG. 3. To obtain a simulation result shown in FIG. 5, for example, a capacitor C having 100 nanofarads is connected to the node B. It is seen that the capacitor C is charged and the output voltage increases.

However, even when the transistor 5 is used instead of the resistor 1, electric power obtained by this configuration is extremely small. A configuration for obtaining a larger output is explained below.

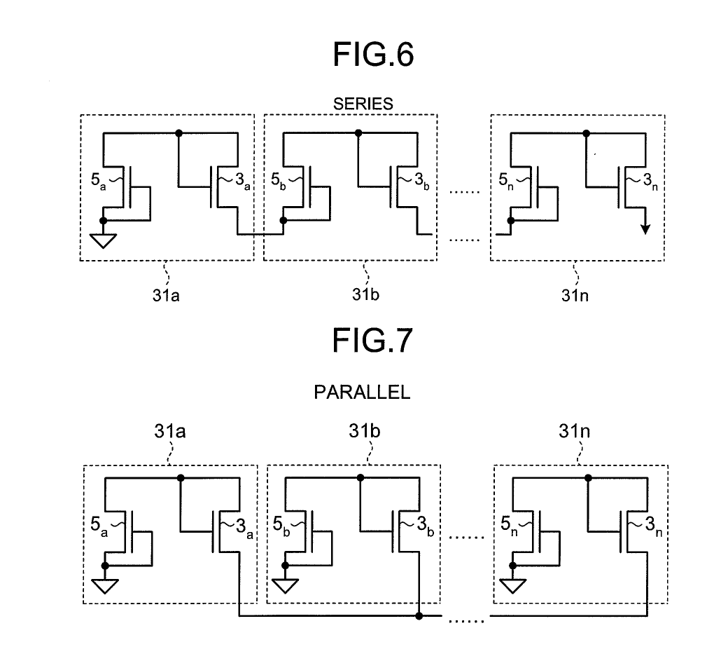

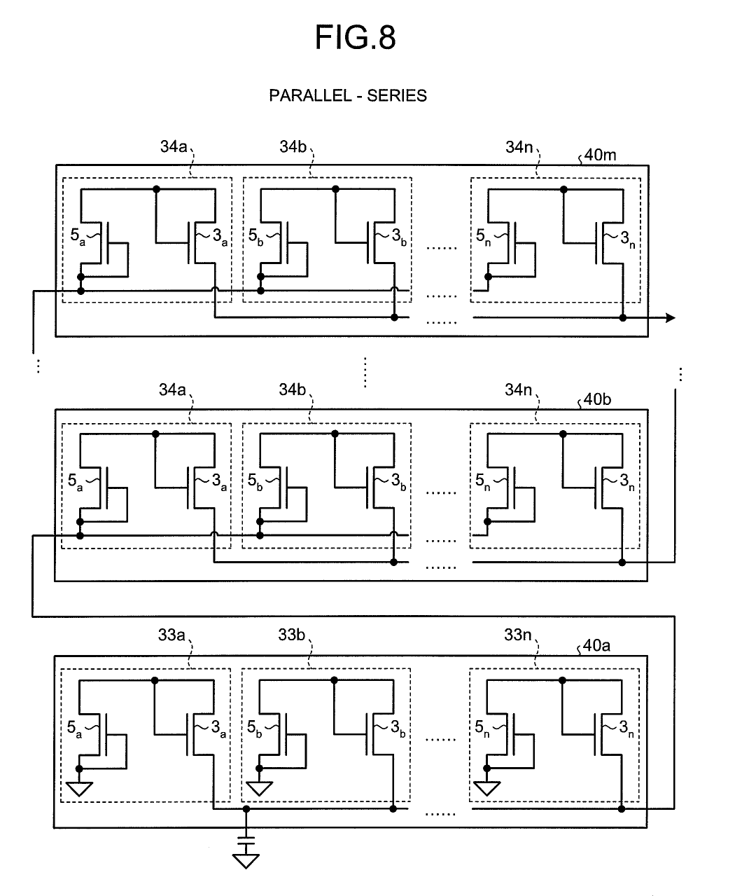

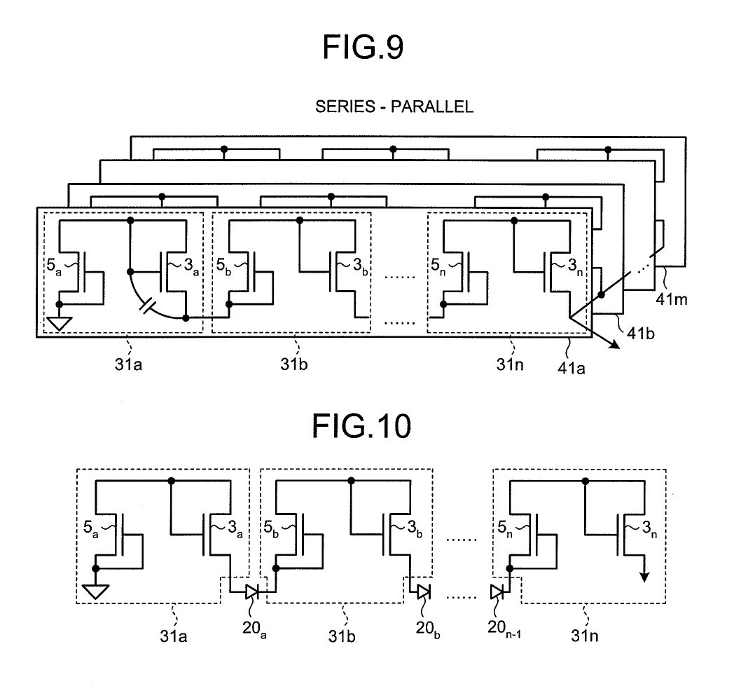

FIG. 6 is a diagram of a configuration example in which a plurality of the semiconductor integrated circuit devices shown in FIG. 3 are connected in series. FIG. 7 is a diagram of a configuration example in which a plurality of the semiconductor integrated circuit devices shown in FIG. 3 are connected in parallel. FIG. 8 is a diagram of a configuration example in which a plurality of sets of the semiconductor integrated circuit devices connected in parallel shown in FIG. 7 are further connected in series. FIG. 9 is a diagram of a configuration example in which a plurality of sets of the semiconductor integrated circuit devices connected in series shown in FIG. 6 are further connected in parallel.

An increase in an output voltage can be realized by connecting a plurality of the circuits shown in FIG. 3 in series. An example of the circuits connected in series is a semiconductor integrated circuit device shown in FIG. 6. In the semiconductor integrated circuit device, one end of the transistor 3 and one end of the transistor 5 are connected to form one unit cell (a driving-voltage generating circuit) 31, the other end of the transistor 3 and the other end of the transistor 5 in the next stage are connected, and a plurality of unit cells 31a to 31n are connected in series. As a result, output voltages of the respective unit cells 31a to 31n are added up and a positive potential is output from the other end of the transistor 31n. The other end of the transistor 5 of the unit cell 31a in the first stage is connected to the GND.

To increase the output current, as shown in FIG. 7, the unit cells 31 only have to be connected in parallel. In a semiconductor integrated circuit device shown in FIG. 7, one end of the transistor 3 and one end of the transistor 5 are connected to form one unit cell 31, the other ends of the transistors 3 are connected in common, and the unit cells 31a to 31n are connected in parallel. The other ends of the transistors 5 are connected to the GND.

In very large-scale integration (VLSI), it is possible to integrate ten million or more transistors. Therefore, even if the electric current of the unit cell 31 alone is lower than a nanoampere level and the voltage thereof is lower than a millivolt level, it is possible to obtain a relatively large output by connecting the transistors in parallel and series or in series and parallel as shown in FIGS. 8 and 9. In a semiconductor integrated circuit device shown in FIG. 8, a driving-voltage generating unit (a second driving-voltage generating unit) 40b, in which a plurality of unit cells (second driving-voltage generating circuits) 34a to 34n are connected in parallel, is connected in series to a driving-voltage generating unit (a first driving-voltage generating unit) 40a, in which a plurality of unit cells (first driving-voltage generating circuits) 33a to 33n are connected in parallel. In the unit cells included in the driving-voltage generating unit 40a, one ends of the transistors 3 and one ends of the transistors 5 are connected, the other ends of the transistors 5 are connected to the GND, and the other ends of the transistors 3 are connected in common and connected to the GND via a capacitor. In the unit cells included in the driving-voltage generating unit 40b, one ends of the transistors 3 and one ends of the transistors 5 are connected and the other ends of the transistors 5 are connected to the other ends connected in common of the transistors 3 of the driving-voltage generating unit 40a. In the semiconductor integrated circuit device shown in FIG. 8, driving-voltage generating units are connected in series in m stages. An output voltage is output from the other ends of the transistors 3 connected in common of the driving-voltage generating unit in the last stage.

In the semiconductor integrated circuit device shown in FIG. 8, relatively large capacitance can be attached to respective parallel output nodes. Therefore, noise components output to the parallel output nodes together with a DC voltage/current are removed. It is possible to prevent the influence on post-stages, i.e., falls in an output voltage and an output current.

A semiconductor integrated circuit device shown in FIG. 9 is a semiconductor integrated circuit device in which a plurality of the semiconductor integrated circuit devices shown in FIG. 6 are connected in parallel. In a first driving-voltage generating unit 41a and a second driving-voltage generating unit 41b, the other ends of the transistors 3 of unit cells in the last stage are connected in common and an output voltage is output from the other ends. In the semiconductor integrated circuit device shown in FIG. 9, driving-voltage generating units are connected in m stages in parallel.

In the semiconductor integrated circuit device shown in FIG. 9, parasitic capacitance attached between output nodes and gates of transistors of the respective unit cells 31 is reduced. Therefore, it is possible to prevent a decrease in power generation per one unit cell 31.

Diodes can also be applied to the semiconductor integrated circuit device according to this embodiment instead of the transistor 3 acting as a rectifying diode and the transistor 5 acting as a resistor. In this case, although the output voltage falls compared with that obtained when the transistors 3 and 5 are used, effects same as those in this embodiment can be obtained.

As explained above, in the semiconductor integrated circuit device according to this embodiment, one end of the transistor 3 and one end of the transistor 5 are connected to form one unit cell. Therefore, it is possible to obtain a driving voltage from atmospheric temperature even if the special semiconductor process disclosed in the document in the past is not used.

FIG. 10 is a diagram of a semiconductor integrated circuit device according to a second embodiment of the present invention. In the semiconductor integrated circuit device shown in FIG. 10, like the semiconductor integrated circuit device shown in FIG. 6, unit cells are connected in series. Further, in the semiconductor integrated circuit device, diodes 20a to 20n−1 are inserted among connection ends of the unit cells. In the semiconductor integrated circuit device shown in FIG. 10, one end of the transistor 3 and one end of the transistor 5 are connected to form one unit cell (a driving-voltage generating circuit) 31, the other ends of the transistors 3 and the other ends of the transistors 5 are connected via the diodes 20a to 20n−1, and the unit cells 31a to 31n are connected in series.

In the case of FIG. 6, it is likely that a minus AC component due to a noise component is included in an output voltage of each of the unit cells, the minus AC component acts to cancel output voltages of the other unit cells, and the output voltage falls. In the semiconductor integrated circuit device according to this embodiment, it is possible to effectively suppress passage of the minus AC component by inserting the diodes 20a to 20n−1 in output stages of the transistors 3. As a result, it is possible to obtain large electric power compared with that in the first embodiment. In this embodiment, the diode is explained as an example of the transistor 3. However, the transistor 3 only has to be an element having a rectifying action. For example, a diode-connected transistor or the like can be used.

The semiconductor integrated circuit devices according to the first and second embodiments include an n-channel meal-oxide semiconductor (NMOS). However, even if a p-channel metal-oxide semiconductor (PMOS) is used instead of the NMOS, it is possible to obtain effects same as those in the first embodiment. Further, it is also possible to mix the NMOS and the PMOS. A specific example of a semiconductor integrated circuit device including both the NMOS and the PMOS is explained below.

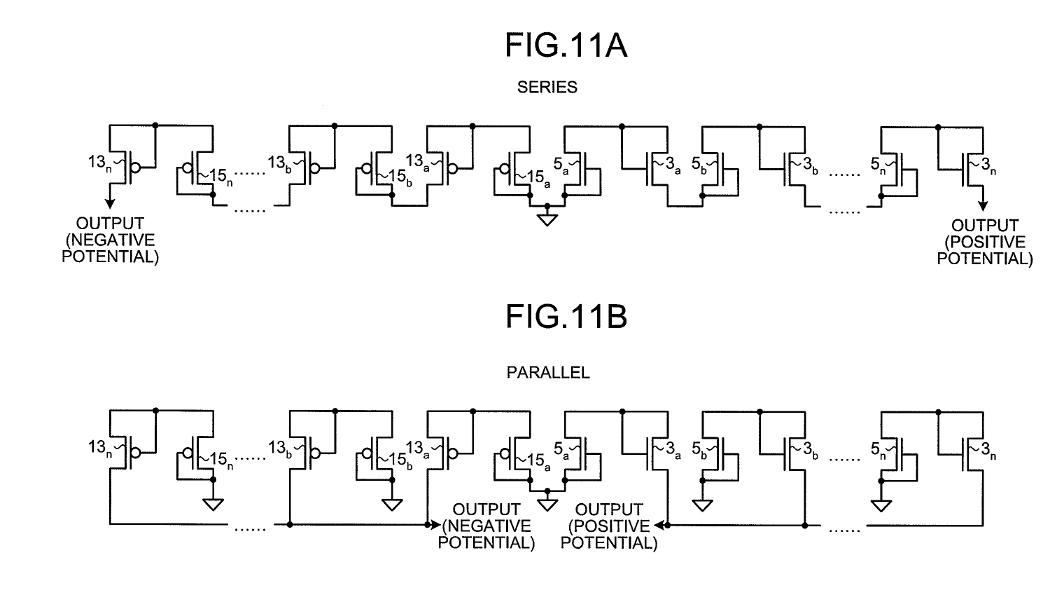

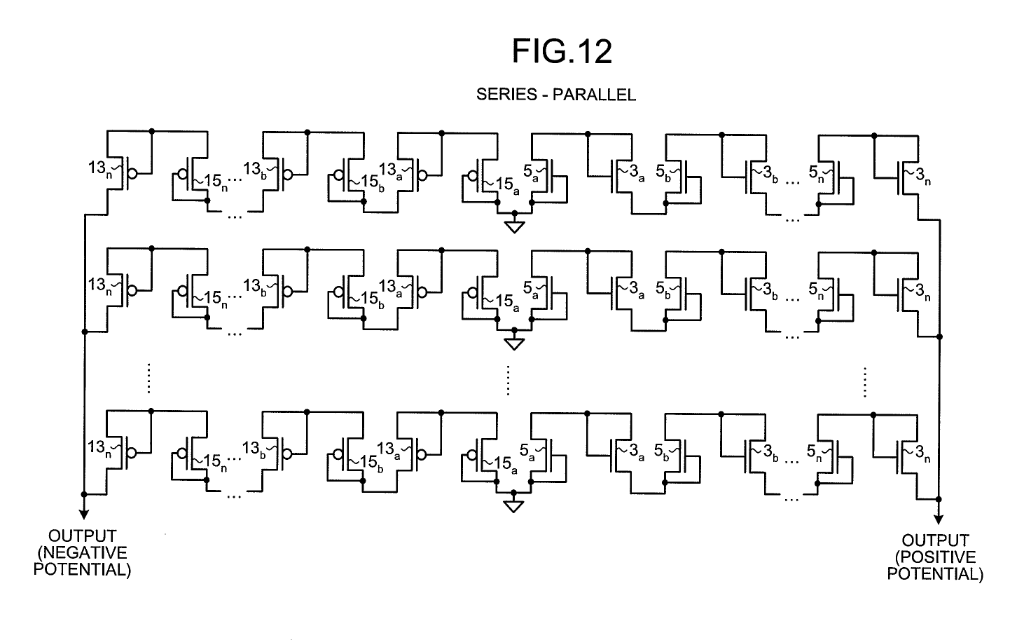

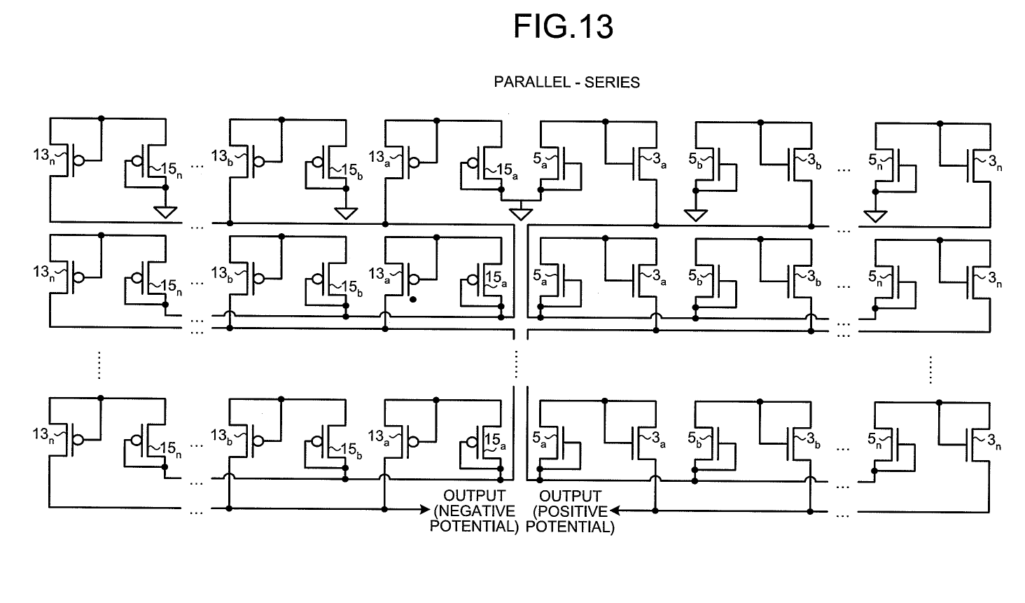

FIG. 11A is a diagram of a configuration example in which semiconductor integrated circuit devices including PMOSs and semiconductor integrated circuit devices including NMOSs are connected in series. FIG. 11B is a diagram of a configuration example in which semiconductor integrated circuit devices including PMOSs and semiconductor integrated circuit devices including NMOSs are connected in parallel. FIG. 12 is a diagram of a configuration example in which a plurality of sets of the semiconductor integrated circuit devices connected in series shown in FIG. 11A are further connected in parallel. FIG. 13 is a diagram of a configuration example in which a plurality of sets of the semiconductor integrated circuit devices connected in parallel shown in FIG. 11B are further connected in series.

An increase in an output voltage can be realized by connecting unit cells in series. For example, as shown in FIG. 11A, the increase in an output voltage can be realized by connecting in series a circuit in which a plurality of unit cells including PMOS transistors are connected in series and a circuit in which a plurality of unit cells including NMOS transistors are connected in series. Specifically, one end of a PMOS transistor 13 and one end of a PMOS transistor 15 are connected to form one unit cell (a first driving-voltage generating circuit), the other end of the transistor 13 and the other end of the transistor 15 are connected, and a plurality of the one unit cells are connected in series (a first driving-voltage generating unit). One end of an NMOS transistor 3 and one end of an NMOS transistor 5 are connected to form the other unit cell (a second driving-voltage generating circuit), the other end of the transistor 3 and the other end of the transistor 5 are connected, and a plurality of the other unit cells are connected in series (a second driving-voltage generating unit). The other end of a transistor 15a and the other end of a transistor 5a are connected to the GND, the first and second driving-voltage generating units are connected in series, a positive potential is output from the other end of a transistor 3n, and a negative potential is output from the other end of a transistor 13n.

An increase in an output current can be realized by, as shown in FIG. 11B, connecting a circuit in which a plurality of unit cells including a plurality of PMOS transistors are connected in parallel and a circuit in which a plurality of unit cells including a plurality of NMOS transistors are connected in parallel. Specifically, one end of the PMOS transistor 13 and one end of the PMOS transistor 15 are connected to form one unit cell (the first driving-voltage generating circuit), the other ends of PMOS transistors 13 are connected in common, and a plurality of the one unit cells are connected in parallel (the first driving-voltage generating unit). The other end of the NMOS transistor 3 and the other end of the NMOS transistor 5 are connected to form the other unit cell (the second driving-voltage generating circuit), the other ends of NMOS transistors 3 are connected in common, and a plurality of the other unit cells are connected in parallel (the second driving-voltage generating unit). The other end of the transistor 15a and the other end of the transistor 5a are connected to the GND, the first and second driving-voltage generating units are connected, a positive potential is output from the other end of the transistor 3a, and a negative potential is output from the other end of the transistor 13a.

When a plurality of sets of the unit cells connected in series are connected in parallel as shown in FIG. 12, it is possible to obtain effects same as those of the semiconductor integrated circuit device shown in FIG. 9. When a plurality of sets of the unit cells connected in parallel are connected in series as shown in FIG. 13, it is possible to obtain effects same as those of the semiconductor integrated circuit device shown in FIG. 8.

In the semiconductor integrated circuit devices according to the first to third embodiments, an output voltage and an output current are obtained by a rectifying action of the transistor 3 or 13. However, in a semiconductor integrated circuit device according to a fourth embodiment, a tunnel diode or a backward diode that makes use of a quantum effect is used as a rectifying device instead of the transistor 3 or 13.

A rectifying action of the tunnel diode or the backward diode is large compared with the rectifying action of the transistor 3 or 13. Therefore, the semiconductor integrated circuit device according to this embodiment can obtain electric power larger than that obtained by the semiconductor integrated circuit devices according to the first to third embodiments.

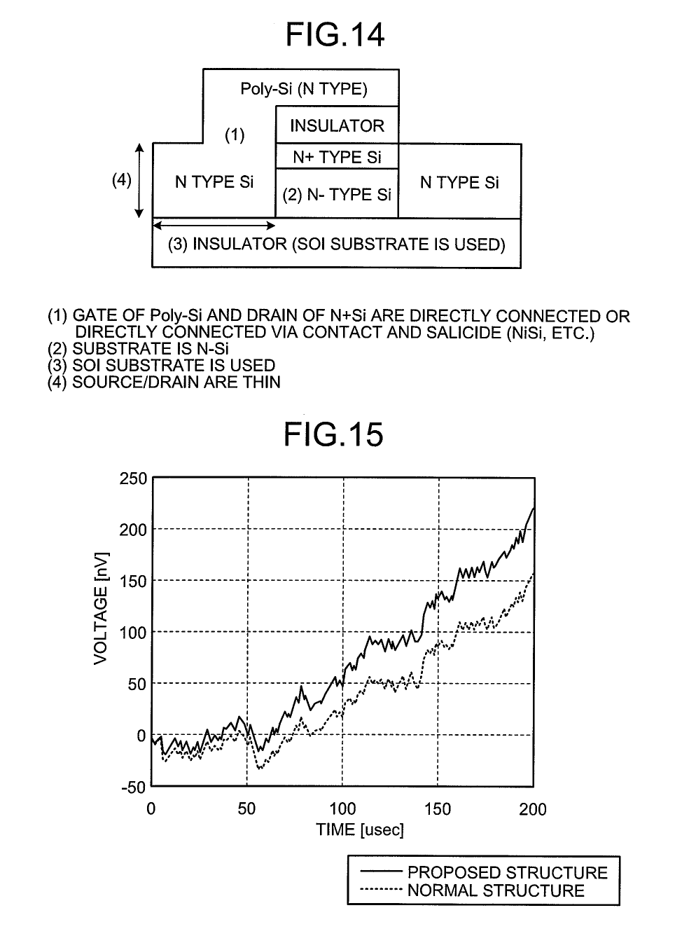

FIG. 14 is a sectional view of a transistor according to a fifth embodiment of the present invention. In the semiconductor integrated circuit devices according to the first to fourth embodiments, to maximize electric power that can be extracted, it is necessary to minimize capacitance attached to the node A as indicated by Formula (2).

Structures (1) to (4) for reducing the capacitance are explained below. As an example, the structures in the case of an NMOS transistor are explained. (1) A gate and a drain of polysilicon are directly connected or the gate and the drain of the polysilicon are directly connected via not-shown contact and salicide (NiSi, etc.). In this case, the gate and the drain can be directly connected without the intervention of not-shown metal. Therefore, it is possible to reduce parasitic capacitance, for example, between wires attached to the gate. (2) A substrate includes an n-type substrate (e.g., N—Si). In this case, it is possible to reduce a threshold of the transistor and reduce parasitic capacitance attached between the drain and the substrate. (3) A silicon on insulator (SOI) substrate is used. By floating the substrate, it is possible to reduce, in capacitance attached between the drain and a back gate, an amount actually contributing as capacitance. (4) A source or the drain is formed thin. It is possible to reduce a joining area of the drain and the substrate and reduce parasitic capacitance attached between the drain and the substrate. More specifically, the height of the drain indicated by an up to down arrow is set to be equal to or smaller than 25% of the length of the drain and the source indicated by a left to right direction.

FIG. 15 is a graph of a change in an output voltage shown in FIG. 5 and a change in an output voltage that occurs when the transistor shown in FIG. 14 is used. Data indicated by a dotted line is data obtained by not adopting the structures (1) to (4). Data indicated by a solid line is data obtained by adopting the structures (1) to (4). Even an NMOS transistor to which any one of the structures (1) to (4) is applied can reduce parasitic capacitance. Two or three of the structures (1) to (4) can be arbitrarily combined and adopted. As a larger number of structures are adopted, it is possible to set the output voltage larger. The output voltage is larger in order of (1), (3), (4), and (2).

A basic NMOS transistor having a two-dimensional structure is shown in FIG. 14. However, the structures (1) to (4) can also be applied to transistors having a three-dimensional structure such as a PMOS transistor and a fin-type field effect transistor (Fin FET). When the structures are applied to the PMOS transistor, N—Si shown in FIG. 14 is read as P—Si and N+Si is read as P+Si.

When the semiconductor integrated circuit devices according to the first to fifth embodiments are incorporated in apparatuses such as a cellular phone, a portable music/video player, and a game machine, it is possible to realize a reduction in size of batteries. In the following explanation, the semiconductor integrated circuit devices according to the first to fifth embodiments are referred to as power generating units. Various apparatuses (loads) are driven by the power generating units.

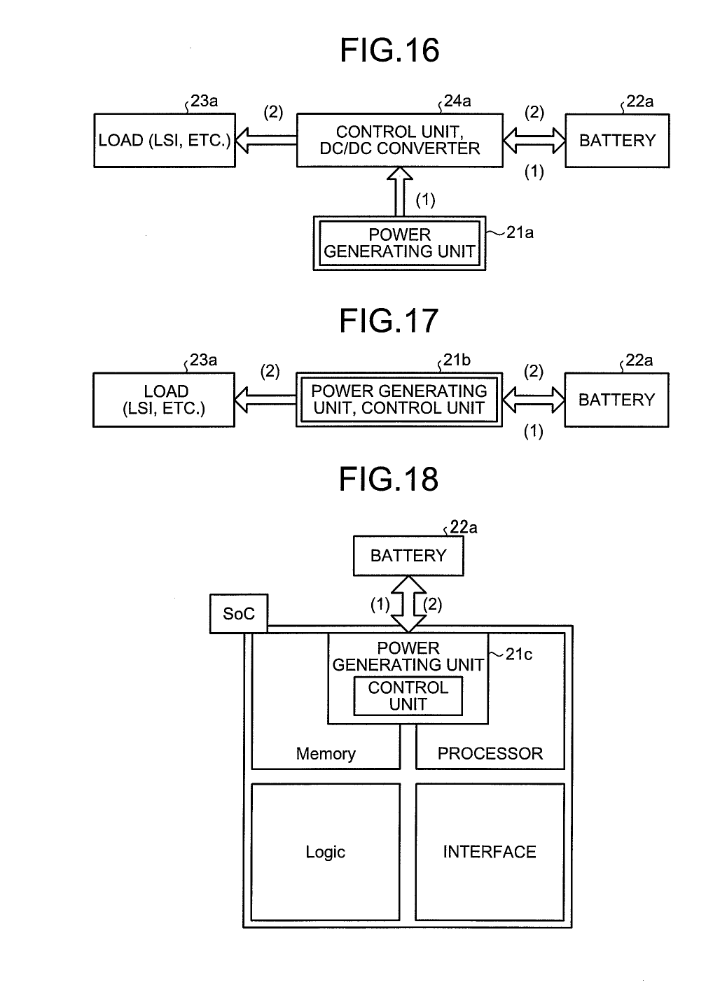

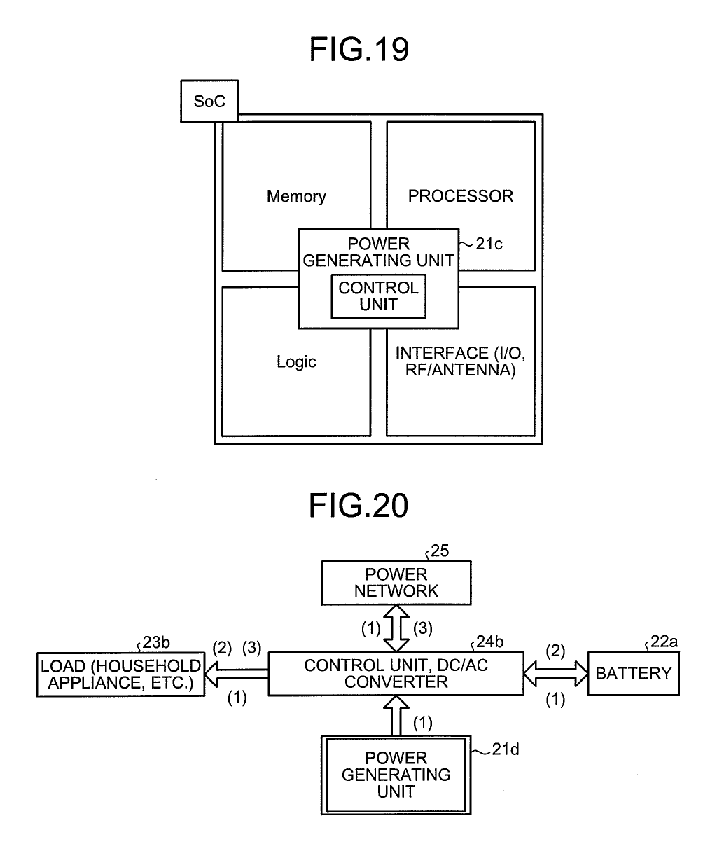

FIG. 16 is a diagram for explaining an example in which a load is driven by a control unit and a power generating unit. FIG. 17 is a diagram of an example in which the power generating unit and the control unit are integrated on one LSI. FIG. 18 is a diagram of one example in which the power generating unit and the control unit are integrated on a SoC. FIG. 19 is the other embodiment in which the power generating unit and the control unit are integrated on the SoC.

In FIG. 16, usually, power consumption during standby of these devices is extremely small. Therefore, during load standby, (1) a battery (an external power supply) 22a is charged by a control unit 24a from a power generating unit 21a. On the other hand, for example, during load use, when electric power required by a load 23a cannot be supply by only the power generating unit 21a, (2) electric power is supplied from the battery 22a to the load 23a by the control unit 24a. The control unit 24a has a function of switching a flow of the electric power according to necessity and has a DC/DC converter for outputting an appropriate DC voltage.

A power generating unit 21b shown in FIG. 17 is a power generating unit in which the power generating unit and the control unit shown in FIG. 16 are integrated on one LSI. A power generating unit 21c shown in FIG. 18 is a power generating unit in which the power generating unit and the control unit shown in FIG. 16 are integrated on a system-on-a-chip (SoC). It is possible to realize a smaller system by integrating the power generating unit and the control unit on one LSI or SoC.

In FIG. 19, when power consumed by the entire SoC can be supplied by only the power generating unit 21c because power consumption of the SoC is sufficiently small or a power generating ability of the power generating unit 21c is sufficiently large, the external battery is unnecessary. Further, if interface with the outside is performed by radio, it is possible to realize a micro-device that does not require wiring to the outside.

FIG. 20 is a diagram for explaining an example in which a load is driven by using a larger number of power generating units. A power generating unit 21d shown in FIG. 20 includes a large number of the power generating units 21a shown in FIG. 16. For example, the power generating unit 21d has a capacity enough for supplying power consumed by a relatively large load 23b such as a household appliance to the load 23b. If such a power generating unit 21d is used, it is possible to use the power generating unit 21d as a power generator for home use. A control unit 24b distributes or switches, according to necessity, for example, (1) charging from the power generating unit 21d to the battery 22a, power supply from the power generating unit 21d to a power network (an external power supply) 25, or power supply from the power generating unit 21d to the load 23b (2) power supply from the battery 22a to the load 23b, and (3) power supply from the power network 25 to the load 23b. In this case, the control unit 24b also performs conversion of a necessary DC voltage and DC-AC conversion. In this way, if the power generating unit 21d is used, it is possible to realize a reduction in weight and extension of life of the battery 22a.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit device comprising a driving-voltage generator comprising a diode-connected rectifying element and a resistor element as a voltage generating source, comprising a first end connected to a first end of the rectifying element and a second end connected to a grounding point, wherein
a voltage output from the resistor element is coupled to a second end of the rectifying element as a driving voltage.

2. The semiconductor integrated circuit device of claim 1, wherein a plurality of the driving-voltage generators are series-connected.

3. The semiconductor integrated circuit device of claim 2, wherein the second end of the rectifying element and a second end of the resistor element in a next stage are connected to the series-connected driving-voltage generators.

4. The semiconductor integrated circuit device of claim 3, wherein the series-connected driving-voltage generators are connected to each another via diodes.

5. The semiconductor integrated circuit device of claim 1, wherein a plurality of the driving-voltage generators are parallel-connected.

6. The semiconductor integrated circuit device of claim 5, wherein the second ends of a plurality of the rectifying elements are connected at one point to the parallel-connected driving-voltage generators.

7. The semiconductor integrated circuit device of claim 1, wherein the resistor element is a diode-connected transistor comprising a diode-connected terminal connected to the grounding point side.

8. The semiconductor integrated circuit device of claim 1, wherein at least one of the rectifying element and the resistor element is on a silicon on insulator (SOI) substrate.

9. The semiconductor integrated circuit device of claim 1, wherein a threshold voltage of the rectifying element is equal to or lower than 0 volt.

10. The semiconductor integrated circuit device of claim 2, wherein a threshold voltage of the resistor element is lower than a threshold voltage of the rectifying element by 50 millivolts or more.

11. The semiconductor integrated circuit device of claim 1, wherein a plurality of the driving-voltage generators are parallel-connected as a driving-voltage generating module, the second ends of a plurality of the rectifying elements of the driving-voltage generating module are connected at a point, and the second ends of the rectifying elements connected at the point are connected to resistor elements of driving-voltage generating modules in a next stage.

12. The semiconductor integrated circuit device of claim 1, wherein a plurality of the driving-voltage generators are series-connected as a driving-voltage generating module, first ends of a plurality of the driving-voltage generating modules are connected, and second ends of the driving-voltage generating modules are connected to a grounding point.

13. A semiconductor integrated circuit device, wherein
a first end of a diode-connected first rectifying element and a first end of a first resistor element as a voltage generating source are connected as a first driving-voltage generator and a plurality of the first driving-voltage generators are connected as a first driving-voltage generating module,
a first end of a diode-connected second rectifying element and a first end of a second resistor element as a voltage generating source are connected as a second driving-voltage generating circuit and a plurality of the second driving-voltage generators are connected as a second driving-voltage generating module, and
the first and second driving-voltage generating modules are connected either in series or in parallel.

14. The semiconductor integrated circuit device of claim 13, wherein the first and second driving-voltage generators are series-connected in the first and second driving-voltage generating modules.

15. The semiconductor integrated circuit device of claim 13, wherein the first and second driving-voltage generators are parallel-connected in the first and second driving-voltage generating modules.

16. The semiconductor integrated circuit device of claim 13, wherein
the first rectifying element and the first resistor element comprise metal-oxide semiconductor (MOS) transistors of a first conduction type, and
the second rectifying element and the second resistor element comprise MOS transistors of a second conduction type.

17. The semiconductor integrated circuit device of claim 13, wherein the rectifying element comprises a tunnel diode.

18. The semiconductor integrated circuit device of claim 13, wherein the rectifying element comprises a backward diode.

19. The semiconductor integrated circuit device of claim 13, comprising:
a power generator comprising the driving-voltage generator; and
a controller configured to supply electric power from either the power generator or an external power supply to a load.

20. The semiconductor integrated circuit device of claim 13, comprising:
a power generator comprising the driving-voltage generator; and
a controller configured to supply electric power from the power generator to an external power supply.
